(19) United States
(12) Patent Application Publication
(10) Pub. No.: US 2011/0074042 A1
(43) Pub. Date: Mar. 31, 2011

(54) ELECTRONIC DEVICE

(75) Inventor: Tatsuaki TSUKUDA, Kanagawa (JP)

(73) Assignee: RENESAS ELECTRONICS CORPORATION, Kawasaki-shi (JP)

(21) Appl. No.: 12/887,093

(22) Filed: Sep. 21, 2010

(30) Foreign Application Priority Data
Sep. 25, 2009 (JP) 2009-221198

(51) Int. Cl. H01L 23/48

(52) U.S. Cl. 257/774; 257/E23.011

(57) ABSTRACT

The electronic device includes the substrate, the electronic component mounted on a main surface of the substrate, a plurality of external terminals formed on a back surface of the substrate, and a plurality of interconnects formed on the back surface of the substrate, wherein the plurality of interconnects includes a first interconnect disposed so as to overlap with an outer edge of the electronic component in a plan view. A pitch between a first external terminal and a second external terminal, adjacent to each other in one direction with the first interconnect located therebetween, is wider than a pitch between a third external terminal and a fourth external terminal, adjacent to each other in the same direction without the first interconnect located therebetween.

This application is based on Japanese patent application No. 2009-221198, the content of which is incorporated hereinto by reference.

### BACKGROUND

1. Technical Field

The present invention relates to an electronic device, and more particularly to en electronic device including an electronic component mounted on a substrate.

2. Related Art

In the electronic device formed in a package structure, which includes an electronic component such as a semiconductor element mounted on a main surface of a substrate, a plurality of external terminals such as solder balls is provided on a back surface of the substrate opposite to the main surface, for connecting the electronic device to a terminal of an external substrate such as a mother board or a printed circuit board. On such back surface of the substrate, also, an interconnect is provided for electrically connecting the external terminal and a via formed in the substrate. The external terminal is electrically connected to the electronic component by means of the interconnect formed on the back surface of the substrate and the via formed in the substrate.

Japanese Laid-Open Utility Publication No. 2003-283081 discloses an auxiliary package for interconnect constituted of a package (electronic device) having an internal circuit and an external terminal array (balls) of a Ball Grid Array (hereinafter, BGA) structure, in which the BGA structure includes a plurality of portions where the balls are aligned in different pitches, such that the pitch P₁ of the balls in an outer periphery of the package is larger than the pitch P₂ of those in a central region of the package, and that the size D₁ of the balls in the outer periphery of the package is larger than the size D₂ of those in the central region of the package. This document then teaches that the auxiliary package for interconnect with the BGA structure allows increasing the ball pitch and the ball size free from constraints by an existing semiconductor IC package, thereby upgrading the implementation reliability and enabling employing an inexpensive printed circuit board.

The conventional substrate with the electronic component mounted thereon, however, has a drawback that the interconnect is prone to suffer disconnection. Through the studies by the present inventors, it has been discovered that the disconnection tends to take place in the interconnect formed so as to bridge over a region overlapping with the electronic component and a region not overlapping therewith in a plan view. Conventionally, the external terminals are disposed in a matrix shape, and the interconnect is provided in a region between the external terminals, i.e. the region where the external terminal is absent. Accordingly, the interconnect has to be formed generally in a narrow line width.

In the substrate with the electronic component mounted thereon, the region overlapping with the electronic component and the region not overlapping therewith exhibit substantial difference in extent of expansion, originating from the heat generation of the electronic component itself, and from the heat treatment performed for mounting the electronic component on the substrate, and for further connecting the electronic device, in which the electronic component has been mounted on the substrate, to the external substrate such as the mother board. Accordingly, in the interconnect formed so as to bridge over the region overlapping with the electronic component and the region not overlapping therewith in a plan view, a portion of such interconnect expands with the expansion of the substrate, while another portion thereof does not, and thus the disconnection of the interconnect is provoked. The narrow line width of the interconnect, typical in the conventional structure, is considered to be a major reason of such disconnection provoked by the expansion of the substrate. In order to increase the line width of the interconnect the pitch between the external terminals has to be extended, however this incurs a disadvantage that the device size has to be increased.

Japanese Laid-Open Utility Publication No. 2003-283081 describes disposing the external terminal array in the outer periphery of the package in a larger pitch, to thereby enable locating a multitude of interconnects and facilitate drawing out the interconnect from the external terminal. According to this document, however, the external terminal array in the inner region of the package is uniformly aligned in a narrower pitch. Such configuration inhibits increasing the line width of the interconnect in the inner region, and is hence unable to solve the foregoing problem of the disconnection.

### SUMMARY

According to the present invention, there is provided an electronic device comprising:

a substrate;

an electronic component mounted on a first surface of the substrate;

a plurality of external terminals formed on a second surface of the substrate; and

a plurality of interconnects formed on the second surface of the substrate;

wherein the plurality of interconnects includes a first interconnect disposed so as to overlap in a plan view with an outer edge of the electronic component; and

a pitch between a first external terminal and a second external terminal among the plurality of external terminals, adjacent to each other in a direction with the first interconnect located therebetween, is wider than a pitch between a third external terminal and a fourth external terminal adjacent to each other in the same direction without the first interconnect located therebetween.

In the electronic device thus constructed, the pitch between the external terminals is wider in the region where the first interconnect, overlapping with the outer edge of the electronic component in a plan view, is located. Such configuration provides a sufficient room that allows increasing the line width of the first interconnect. Increasing the line width of the first interconnect allows preventing the disconnection of the interconnect, even in the case where the region overlapping with the electronic component and the region not overlapping therewith exhibit substantial difference in extent of expansion of the substrate, resultant from the heat generation of the electronic component itself, and from the heat treatment performed for mounting the electronic component on the substrate, and for further connecting the electronic device, in which the electronic component has been mounted on the substrate, to the external substrate such as the mother board. Yet, the external terminals can be disposed in a narrower pitch in the remaining region, and therefore the layout pattern can be formed without compromise in the number of external terminals. Such configuration allows, consequently, effectively preventing the disconnection without incurring an increase in size of the electronic device, and upgrading the implementation reliability.

It is to be noted that any optional combination of the foregoing constituents, and a conversion of the expression of the present invention between a method and a device, are also included in the scope of the present invention.

Thus, the present invention enables effectively preventing the disconnection of the interconnect formed on the substrate, without incurring an increase in size of the electronic device including the electronic component mounted on the substrate.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view showing a structure of an electronic device according to an embodiment of the present invention;

FIG. 2 is a plan view showing an example of a structure of a back surface of a substrate of the electronic device, according to the embodiment of the present invention;

FIGS. 3A and 3B are plan views for explaining a designing process of a layout on the back surface of the substrate shown in FIG. 2;

FIG. 4 is a plan view showing another example of the structure of the back surface of the substrate of the electronic device, according to the embodiment of the present invention;

FIG. 5 is a plan view showing still another example of the structure of the back surface of the substrate of the electronic device, according to the embodiment of the present invention;

FIGS. 6A and 6B are plan views for explaining a designing process of the layout on the back surface of the substrate shown in FIG. 5;

FIG. 7 is a plan view showing still another example of the structure of the back surface of the substrate of the electronic device, according to the embodiment of the present invention;

FIG. 8 is a plan view showing still another example of the structure of the back surface of the substrate of the electronic device, according to the embodiment of the present invention;

FIG. 9 is a plan view showing still another example of the structure of the back surface of the substrate of the electronic device, according to the embodiment of the present invention;

FIG. 10 is a plan view showing another example of the structure of the electronic device according to the embodiment of the present invention; and

FIG. 11 is a plan view showing still another example of the structure of the electronic device according to the embodiment of the present invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereunder, an embodiment of the present invention will be described in details, referring to the drawings. In all the drawings, the same constituents will be given the same numeral, and the description thereof will not be repeated.

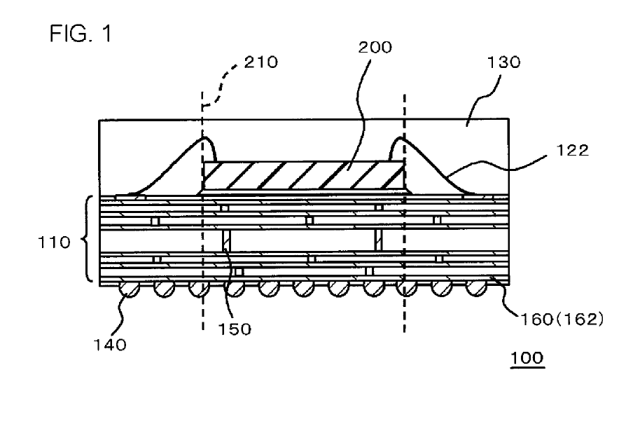

FIG. 1 is a cross-sectional view showing a structure of an electronic device according to this embodiment.

The electronic device 100 includes a substrate 110, an electronic component 200 mounted on a main surface (upper face according to the orientation of FIG. 1) of the substrate 110, and a plurality of external terminals 140 provided on a back surface (lower face according to the orientation of FIG. 1) of the substrate 110. The electronic component 200 may be a semiconductor element such as a semiconductor chip, or a passive element such as a capacitor. In this embodiment, it may be assumed that the electronic component 200 is a semiconductor chip. The electronic component 200 is electrically connected to a terminal on the surface of the substrate 110 through a bonding wire 122. Also, the electronic component 200 and the bonding wire 122 are enclosed in an encapsulating resin 130.

The substrate 110 may be a circuit board including a interconnect layer. In this embodiment, it may be assumed that the substrate 110 is a multilayer circuit board including a plurality of interconnect layers. The substrate 110 includes therein a via (through hole) 150 that electrically connects the interconnects of the different interconnect layers. A portion of the via 150 is exposed on the back surface of the substrate 110. This embodiment exemplifies the case where the electronic device 100 is a BGA package. In this case, the external terminal 140 may be constituted of an electrode pad to be subsequently described, which is simultaneously formed with the interconnect on the back surface of the substrate 110, and a solder ball formed on the surface of the electrode pad. Alternatively, the electronic device 100 may be a Land Grid Array (LGA) package without the solder ball.

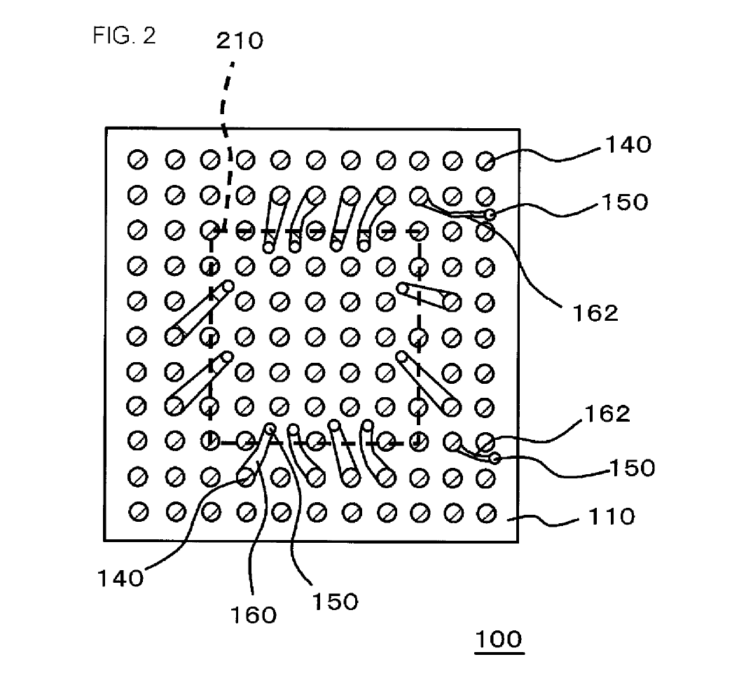

FIG. 2 is a plan view showing an example of the structure of the back surface of the substrate 110 of the electronic device 100, according to this embodiment.

On the back surface substrate 110, a plurality of interconnects is provided, which includes a first interconnect 160 and a second interconnect 162.

The first interconnect 160 and the second interconnect 162 serve to electrically connect the via 150 and the external terminal 140. The first interconnect 160 serves to electrically connect the via 150 located in one of an inner region of an electronic component edge 210 and an outer region thereof, and one of the external terminals 140 located in the other of the inner region of the electronic component edge 210 and the outer region thereof. The first interconnect 160 is located so as to overlap with the electronic component edge 210 in a plan view. It is to be underlined that in this embodiment the first interconnect 160 extends, in a plan view, so as to intersect the electronic component edge 210, i.e. the outer edge of the electronic component 200, from the inner region to the outer region thereof. In contrast, the second interconnect 162 does not overlap with the electronic component edge 210 in a plan view. In other words, the second interconnect 162 is not arranged so as to intersect the electronic component edge 210.

Also, the first interconnect 160 is formed in a wider line width than the second interconnect 162. For example, the line width of the first interconnect 160 may be somewhere between the diameter of the via 150 and that of the external terminal 140 of a ball land structure, and more specifically may be approx. 350 μm. In contrast, the second interconnect 162 may be formed in a minimum line width according to the minimum design rule, and more specifically approx. 20 to 70 μm. Here, the “line width” may be taken as the average of the overall path from the via 150 to the external terminal 140. In particular, the first interconnect 160 is formed in a wider line width in the portion overlapping with the electronic component edge 210. In this embodiment, also, the first interconnect 160 and the second interconnect 162 may serve as a signal line through which a signal to the electronic component 200 is to be inputted, outputted, or input/outputted.

As stated earlier, the region on the substrate 110 overlapping with the electronic component 200 and the region not overlapping therewith exhibit substantial difference in extent of expansion, originating from the heat generation of the electronic component 200 itself, and from the heat treatment performed for mounting the electronic component 200 on the substrate 110, and for further connecting the electronic device 100 to the external substrate such as the mother board. In the case where the interconnect is disposed so as overlap with the electronic component edge 210, such interconnect extends over both the region overlapping with the electronic component 200 and the region not overlapping with the electronic component 200. Accordingly, when the substrate 110 expands, a portion of the interconnect expands while another portion thereof does not, and such phenomenon may provoke the disconnection of the interconnect. Especially in the case where the interconnect extends so as to intersect the electronic component edge 210 from an inner region to an outer region thereof, the disconnection is more prone to take place. Here, the expression of “extend so as to intersect” refers to a state that the extending direction of the interconnect generally orthogonal to the line width intersects the electronic component edge 210. In this embodiment, forming such interconnect in a wider line width as the first interconnect 160 allows preventing the disconnection of the interconnect.

In this embodiment, the plurality of external terminals 140 is disposed generally in a matrix shape on the back surface of the substrate 110, in one direction (vertical direction in FIG. 2) and in the other direction orthogonal thereto (horizontal direction in FIG. 2). Among the plurality of external terminals 140, a pitch between two terminals 140 (a first external terminal and a second external terminal) adjacent to each other in one direction (or horizontal direction) with the first interconnect 160 located therebetween is larger than a pitch between other two external terminals 140 (a third external terminal and a fourth external terminal) adjacent to each other in the same direction but without the first interconnect 160 located therebetween. It is to be noted that between the external terminals 140 adjacent to each other with the first interconnect 160 located therebetween, the external terminal 140 that would otherwise be located in the matrix shape is absent. In this embodiment, also, the first interconnect 160 is disposed so as to extend between such external terminals 140 that are located close to and along the electronic component edge 210, and the pitch between such external terminals 140 is larger.

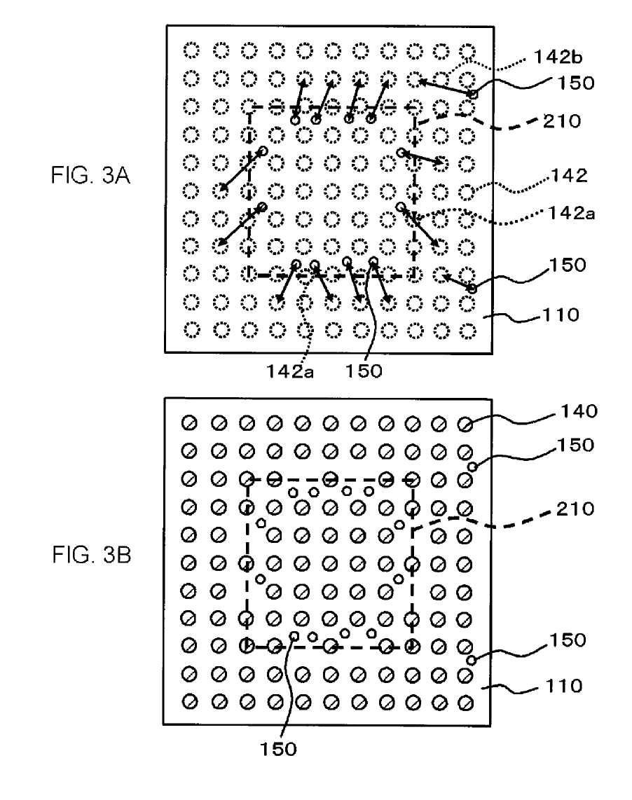

FIGS. 3A and 3B are plan views for explaining a designing process of the layout on the back surface of the substrate 110 shown in FIG. 2.

In this embodiment, the layout of the external terminals 140 may be determined as follows.

First, as shown in FIG. 3A, tentative positions 142 of the plurality of external terminals are disposed in the matrix shape at a regular pitch, in one direction and in the other direction orthogonal thereto. FIG. 3A illustrates the example where the tentative positions 142 of the external terminals are uniformly disposed in one direction and in the other direction orthogonal thereto. The tentative position 142 is the positions where the external terminal 140 may subsequently be formed. For example, the tentative position 142 may be aligned in a matrix shape of M rows by N columns. This embodiment represents the case where M and N are both 11.

Then an interconnect pattern is determined, in consideration of the positional relationship between the external terminal 140 to be formed on the respective tentative position 142 and the via 150. It is to be herein assumed that the external terminal 140 to be formed on the tentative position 142 indicated by arrows in FIG. 3A, and the via 150 indicated by the respective arrows are electrically connected through the interconnect.

In the case where the line connecting the via 150 and the tentative position 142 intersects the electronic component edge 210, the interconnect that connects the external terminal 140 formed on the relevant tentative position 142 and the via 150 has to be formed as the first interconnect 160 having a wider line width. Accordingly, in order to secure the room for forming the first interconnect 160, it is not preferable that the external terminal 140 is formed on the tentative position 142 located close to the line intersecting the electronic component edge 210 for connecting the via 150 and the tentative position 142. For example, it is not preferable to form the external terminal 140 on the tentative positions 142a shown in FIG. 3A. Accordingly, the tentative positions 142a are eliminated.

In contrast, in the case where the line connecting the via 150 and the tentative position 142 does not intersect the electronic component edge 210, the interconnect that connects the external terminal 140 formed on the relevant tentative position 142 and the via 150 may be formed as the second interconnect 162 having a narrower line width. The second interconnect 162 may be formed utilizing a space available between the tentative positions 142 disposed in the matrix shape. Accordingly, although the tentative position 142b in FIG. 3A is located close to the line connecting the tentative position 142 and the via 150, the external terminal 140 may be formed on the tentative position 142b. The tentative position 142b is therefore preserved as it is.

Then the external terminals 140 are formed on the positions corresponding to the tentative positions 142 that have been preserved, and also the first interconnect 160 and the second interconnect 162 are formed. Thus, the layout as shown in FIG. 2 can be obtained. In this embodiment, as shown in FIG. 2, among the external terminals 140 equidistantly located from the outer edge of the substrate 110, the pitch between the external terminals 140 adjacent to each other in one direction with the first interconnect 160 located therebetween is larger than the pitch between other external terminals 140 adjacent to each other in the same direction without the first interconnect 160 located therebetween. For example, among the external terminals 140 in the third column from the right in FIG. 2, the pitch between the external terminals 140 vertically adjacent to each other with the first interconnect 160 located therebetween is larger than the pitch between other external terminals 140 vertically adjacent to each other without the first interconnect 160 located therebetween.

FIG. 3B is a plan view showing the external terminals 140 and the vias 150 formed on the back surface of the substrate 110. For clearer understanding of the layout of the external terminals 140, the first interconnect 160 and the second interconnect 162 are excluded from FIG. 3B. In this embodiment, with reference to the external terminals 140 formed at the positions overlapping with the electronic component edge 210, eliminating some of the tentative positions 142 results in expanding the pitch between some adjacent pairs of the external terminals 140 among those formed along the electronic component edge 210.

In FIGS. 2 to 3B, the via and the interconnect unrelated to the description of the present invention are not shown.

The electronic device 100 may be configured in various different manners, some of which will be described hereunder.

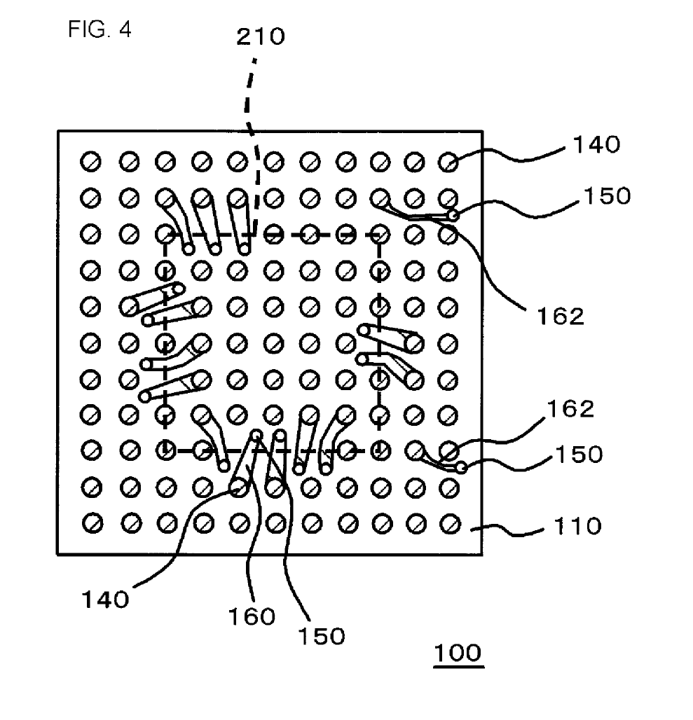

FIG. 4 is a plan view showing another example of the structure of the back surface of the substrate of the electronic device according to this embodiment.

In the example shown in FIGS. 2 to 3B, the first interconnect 160 is formed generally symmetrically, both horizontally and vertically, with respect to the center of the substrate 110. Instead, the first interconnect 160 may be randomly disposed as shown in FIG. 4.

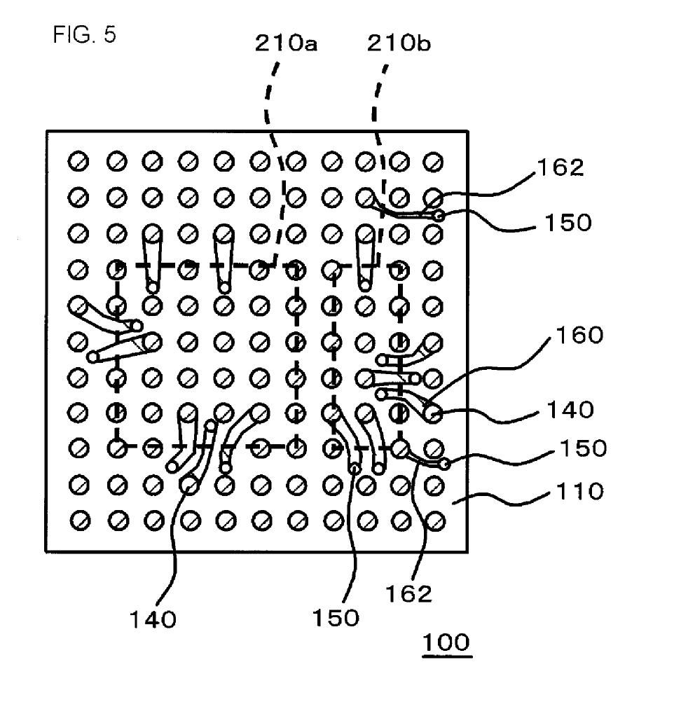

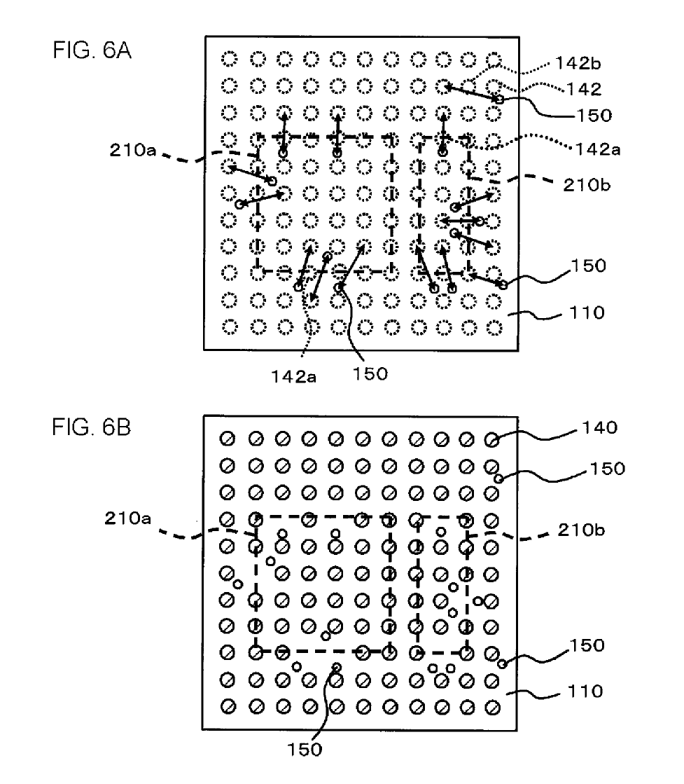

FIG. 5 is a plan view showing still another example of the structure of the back surface of the substrate of the electronic device according to this embodiment. FIGS. 6A and 6B are plan views for explaining a designing process of the layout on the back surface of the substrate shown in FIG. 5.

While a single electronic component 200 is mounted on the substrate 110 in the example shown in FIGS. 1 to 3B, a plurality of electronic components 200 may be located side by side on the substrate 110. In this case, the region overlapping with the edge of the electronic component 200 in a plan view is created with respect to each of the electronic components 200. In the examples shown in FIGS. 5,6A and 6B, two electronic components 200 are mounted on the substrate 110. Now, the edge of one of the electronic components 200 will be referred to as a first electronic component edge 210a, and that of the other electronic component 200 as a second electronic component edge 210b.

In such structure also, the interconnect formed so as to intersect the first electronic component edge 210a or the second electronic component edge 210b may be formed as the first interconnect 160, with a wider line width.

For the examples shown in FIGS. 5,6A and 6B also, the pattern can be designed in a way similar to the process described referring to FIG. 3A. First, as shown in FIG. 6A, the tentative positions 142 of the external terminals are disposed in the matrix shape at a regular pitch, in one direction and in the other direction orthogonal thereto. This example also represents the case where M and N are both 11.

Then the interconnect pattern is determined, in consideration of the positional relationship between the external terminal 140 to be formed on the respective tentative position 142 and the via 150. It is equally assumed that the external terminal 140 to be formed on the tentative position 142 indicated by arrows in FIG. 6A, and the via 150 indicated by the respective arrows are electrically connected through the interconnect.

In the case where the line connecting the via 150 and the tentative position 142 intersects the first electronic component edge 210a or the second electronic component edge 210b, the interconnect that connects the external terminal 140 formed on the relevant tentative position 142 and the via 150 has to be formed as the first interconnect 160 having a wider line width. Accordingly, in order to secure the room for forming the first interconnect 160, the tentative positions 142a located close to the line connecting the via 150 and the tentative position 142 are eliminated.

In contrast, in the case where the line connecting the via 150 and the tentative position 142 does not intersect the first electronic component edge 210a or the second electronic component edge 210b, the interconnect that connects the external terminal 140 formed on the relevant tentative position 142 and the via 150 may be formed as the second interconnect 162 having a narrower line width. Accordingly, for example the tentative position 142b in FIG. 6A is preserved as it is.

Then the external terminals 140 are formed on the positions corresponding to the tentative positions 142 that have been preserved, and also the first interconnect 160 and the second interconnect 162 are formed. Thus, the layout as shown in FIG. 5 can be obtained.

FIG. 6B is a plan view showing the external terminals 140 and the vias 150 formed on the back surface of the substrate 110. For clearer understanding of the layout of the external terminals 140, the first interconnect 160 and the second interconnect 162 are excluded from FIG. 6B. In this embodiment, with reference to the external terminals 140 formed at the positions overlapping with the first electronic component edge 210a or the second electronic component edge 210b, eliminating some of the tentative positions 142 results in expanding the pitch between some adjacent pairs of the external terminals 140 among those formed along the first electronic component edge 210a and the second electronic component edge 210b.

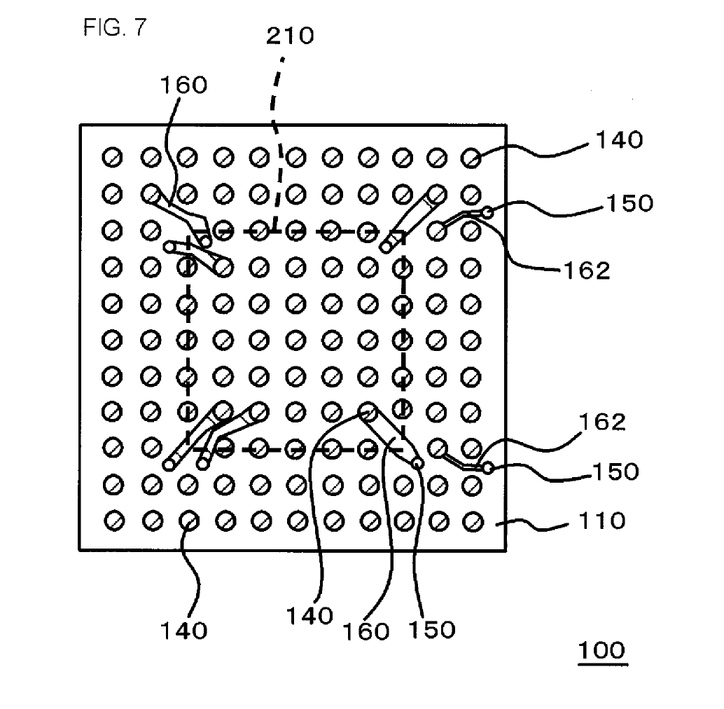

FIGS. 7 to 9 are plan views each showing still another example of the structure of the back surface of the substrate of the electronic device according to the embodiment.

These examples represent the case where the first interconnect 160 is formed so as to intersect a corner portion of the electronic component edge 210.

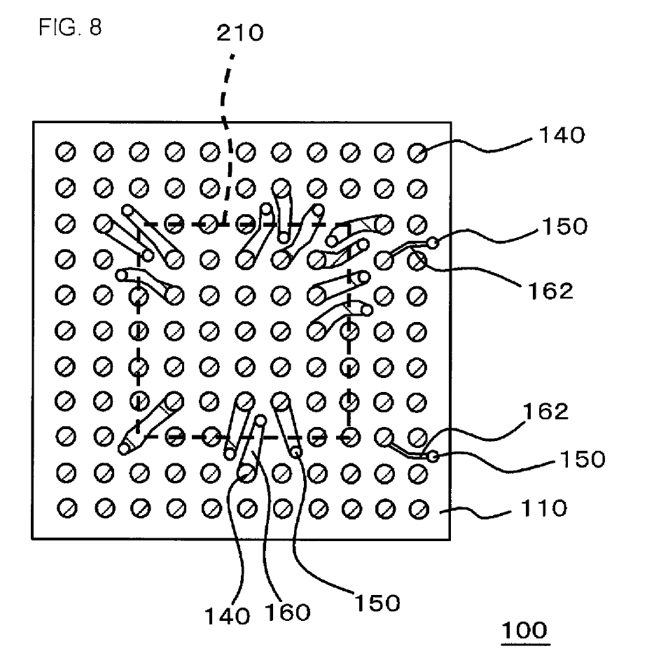

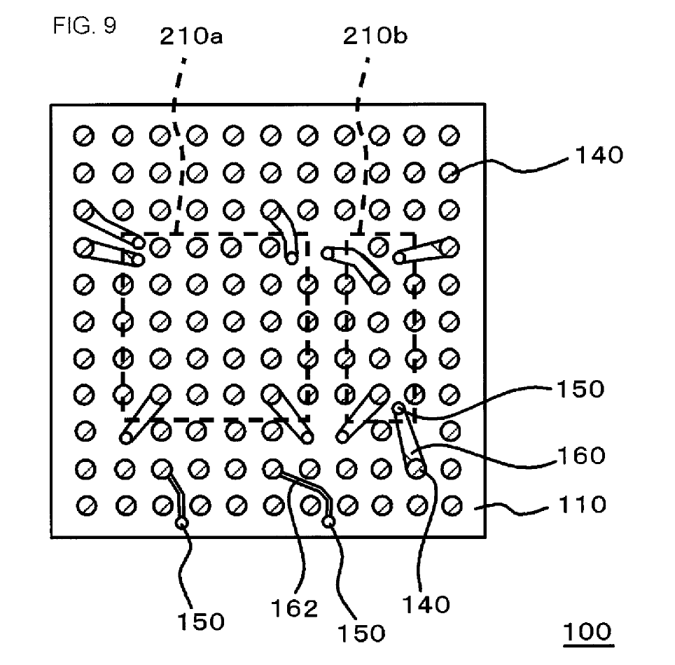

FIGS. 7 and 8 show a structure that includes a single electronic component edge 210, and FIG. 9 shows a structure that includes both the first electronic component edge 210a and the second electronic component edge 210b.

The corner portion of the region on which the electronic component 200 is mounted is prone to suffer point-concentrated stress, which often provokes expansion of the substrate 110. For such reason the conventional interconnect having a narrow line width is prone to be disconnected. In this embodiment, however, the first interconnect 160 having a wider line width is provided on such corner portions, and therefore the disconnection can be prevented.

Hereunder, description will be given on advantageous effects offered by the electronic device 100 according to this embodiment.

In the electronic device 100 according to this embodiment, the external terminals 140 are formed in a wider pitch at the position where the first interconnect 160 overlaps with the electronic component edge 210, and hence a sufficient room can be secured for increasing the line width of the first interconnect 160. Increasing the line width of the first interconnect 160 allows preventing the disconnection of the interconnect, even in the case where the region on the substrate 110 overlapping with the electronic component and the region not overlapping therewith exhibit substantial difference in extent of expansion originating from the heat generation of the electronic component 200.

Also, the line width of the first interconnect 160 overlapping with the electronic component edge 210 is selectively increased rather than uniformly increasing the line width of all the interconnects, and the second interconnect 162 is located at the position not overlapping with the external terminal 140 disposed in the matrix shape. Such configuration allows locating in a narrower pitch the other external terminals 140 than those located close to the first interconnect 160, and thereby enables forming the pattern without compromise in the number of external terminals 140, and in the number of second interconnects 162.

Thus, the present invention enables effectively preventing the disconnection without increasing the size of the electronic device 100, and thereby upgrading the reliability of the device.

Although the embodiment of the present invention has been described referring to the drawings, it is to be understood that the foregoing embodiment is merely exemplary and that various different configurations may be adopted.

In the foregoing embodiment, a plurality of electronic components 200 may be stacked in the region delimited by the electronic component edge 210, the first electronic component edge 210a, and the second electronic component edge 210b.

Also, though the foregoing embodiment refers to the interconnect formed on the back surface of the substrate 110, on which the external terminals 140 made of the solder ball or the like are provided, the first interconnect 160 and the second interconnect 162 may be similarly formed on another region on the substrate 110. For example, on the main surface of the substrate 110 on which the electronic component 200 is mounted, and in one of the layers of the multilayer structure of the substrate 110, the interconnect disposed so as to overlap with the electronic component edge 210 in a plan view may be formed as the first interconnect 160 in a wider line width than the remaining interconnects. Here, the interconnect may serve as a signal line through which a signal to the electronic component 200 is to be inputted, outputted, or input/outputted.

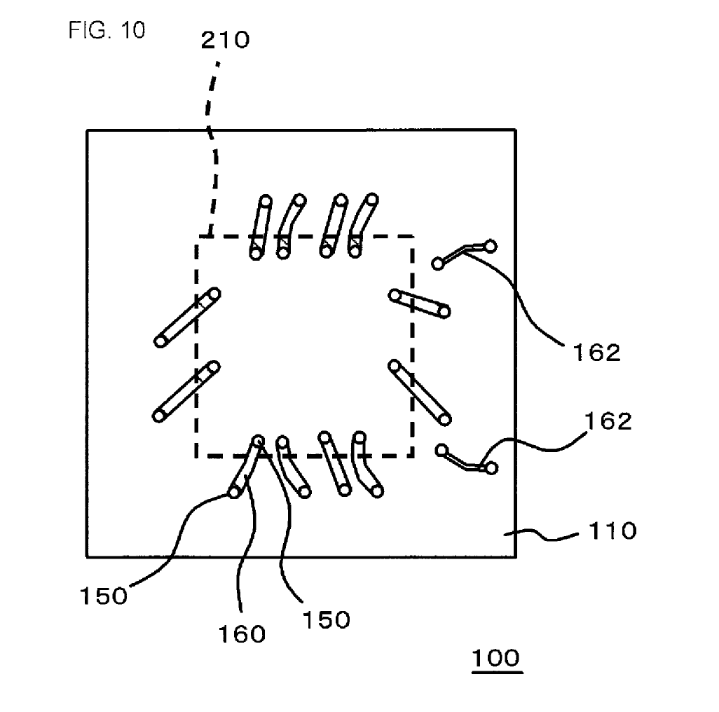

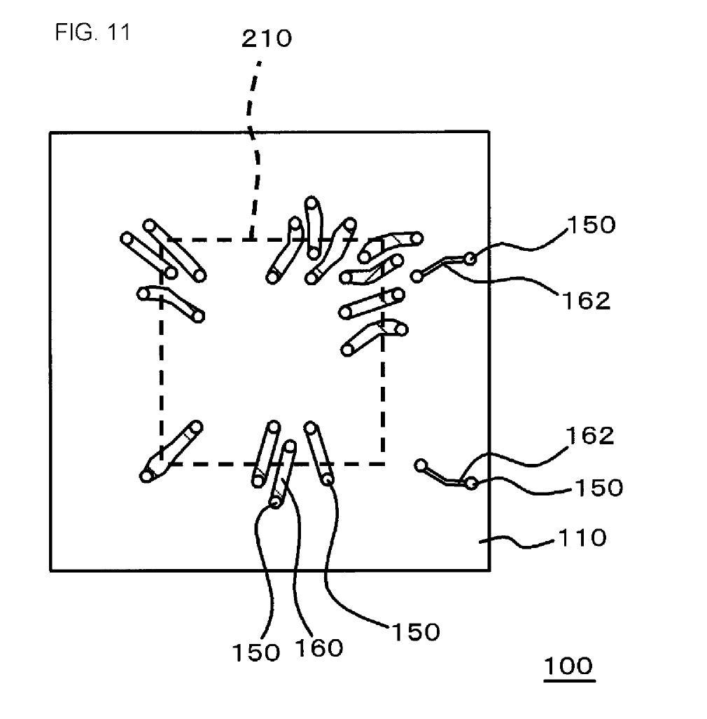

FIGS. 10 and 11 represent the latter case.

These drawings depict a part of a pattern formed in one of the layers of the multilayer structure of the substrate 110. Such via and interconnect that are unrelated to the description of the present invention are not shown in FIGS. 10 and 11. As is apparent from these drawings, the first interconnect 160 having a wider line width is formed in the case where the interconnect connecting between a plurality of vias 150 overlaps with and intersects the electronic component edge 210. In contrast, in the case where the interconnect is formed so as not to intersect the electronic component edge 210, the second interconnect 162 is formed in a narrower line width.

It is also to be noted that the electronic device 100 according to the present invention is eventually mounted on an external substrate such as a mother board and a printed circuit board. Accordingly, the present invention is also applicable to an electronic device, which is a finished product including the external substrate and the electronic device 100.

It is apparent that the present invention is not limited to the above embodiment, and may be modified and changed without departing from the scope and spirit of the invention.

What is claimed is:

1. An electronic device comprising:
a substrate;
an electronic component mounted on a first surface of said substrate;
a plurality of external terminals formed on a second surface of said substrate; and
a plurality of interconnects formed on said second surface of said substrate;
wherein said plurality of interconnects includes a first interconnect disposed so as to overlap in a plan view with an outer edge of said electronic component; and
a pitch between a first external terminal and a second external terminal among said plurality of external terminals, adjacent to each other in one direction with said first interconnect located therebetween, is wider than a pitch between a third external terminal and a fourth external terminal adjacent to each other in said one direction without said first interconnect located therebetween.

2. The electronic device according to claim 1,
wherein said first interconnect extends so as to intersect said outer edge of said electronic component, from an inner region to an outer region thereof.

3. The electronic device according to claim 1,
wherein said first external terminal and said second external terminal are located adjacent to each other close to said outer edge of said electronic component and along said outer edge.

4. The electronic device according to claim 3,
wherein said third external terminal and said fourth external terminal are located close to said outer edge of said electronic component and along said outer edge.

5. The electronic device according to claim 1,
wherein said first interconnect has a wider line width than another interconnect disposed so as not to overlap with said outer edge of said electronic component.

6. The electronic device according to claim 1,
wherein a pitch between said first external terminal and said second external terminal is made wider, by eliminating a tentative position for said external terminal located between said first external terminal and said second external terminal, out of a plurality of tentative positions disposed on said back surface of said substrate external terminal at a regular pitch in a direction and in another direction orthogonal thereto, and forming said external terminal on positions corresponding to said tentative positions that have not been eliminated.

7. The electronic device according to claim 1,
wherein said plurality of external terminals is disposed in a matrix shape on said back surface of said substrate, in one direction and in another direction orthogonal thereto.

8. The electronic device according to claim 1, further comprising:
a via formed in said substrate so as to be exposed on said back surface of said substrate;
wherein said via is located in one of an inner region of said outer edge of said electronic component edge and an outer region thereof; and
said first interconnect is electrically connected to said via and to one of said external terminals located in the other of said inner region of said outer edge of said electronic component edge and said outer region thereof.
